(19) United States
(12) Patent Application Publication
(10) Pub. No.: US 2023/0100702 A1
(43) Pub. Date: Mar. 30, 2023

(54) SUBSTRATE PROCESSING APPARATUS, METHOD OF MANUFACTURING SEMICONDUCTOR DEVICE AND NON-TRANSITORY COMPUTER READABLE RECORDING MEDIUM

(71) Applicant: Kokusai Electric Corporation, Tokyo (JP)

(72) Inventors: Tatsuki JINDEN, Toyama-shi (JP); Yusaku OKAJIMA, Toyama-shi (JP); Yuji TAKEBAYASHI, Toyama-shi (JP)

(73) Assignee: Kokusai Electric Corporation, Tokyo (JP)

(21) Appl. No.: 17/903,515

(22) Filed: Sep. 6, 2022

(30) Foreign Application Priority Data
Sep. 24, 2021 (JP) 2021-155723

(51) Int. Cl. H01L 21/67; C23C 16/458; C23C 16/455; C23C 16/46

(52) U.S. Cl. CPC H01L 21/67017; C23C 16/4584; C23C 16/45563; C23C 16/46; H01L 21/67313

(57) ABSTRACT

There is provided a technique capable of uniformly supplying a gas with respect to a surface of a substrate when the substrate is processed. According to one aspect thereof, there is provided a substrate processing apparatus including: a reaction tube; and a gas supply nozzle for supplying a gas to a substrate supported by a substrate support in the reaction tube along a direction parallel to a substrate surface. The gas supply nozzle is provided with a gas ejection port including an edge vicinity portion and a central portion defined along the direction parallel to the surface of the substrate. An opening dimension of the edge vicinity portion of the gas ejection port measured along a direction orthogonal to the direction parallel to the surface of the substrate is greater than an opening dimension of the central portion of the gas ejection port measured along the same direction.

### CROSS-REFERENCE TO RELATED PATENT APPLICATION

This non-provisional U.S. patent application is based upon and claims priority under 35 U.S.C. § 119 of Japanese Patent Application No. 2021-155723, filed on Sep. 24, 2021, in the Japanese Patent Office, the entire contents of which are hereby incorporated by reference.

### BACKGROUND

### 1. Field

The present disclosure relates to a substrate processing apparatus, a method of manufacturing a semiconductor device and a non-transitory computer-readable recording medium.

### 2. Related Art

A batch type vertical processing apparatus may be used as a substrate processing apparatus used in a part of a manufacturing process of a semiconductor device. The batch type vertical processing apparatus is configured such that a plurality of substrates (wafers) are capable of being accommodated in a process furnace while being supported by a substrate support (which is a boat), and a process such as a film-forming process and a heat treatment process is capable of being performed with respect to the substrates accommodated in the process furnace by supplying a gas to the substrates along a direction of a surface of each of the substrates.

### SUMMARY

According to the present disclosure, there is provided a technique capable of uniformly supplying a gas with respect to a surface of a substrate when the substrate is processed.

According to one aspect of the technique of the present disclosure, there is provided a substrate processing apparatus including: a reaction tube in which a substrate support configured to support a substrate is accommodated; and a gas supply nozzle through which a gas is supplied with respect to the substrate supported by the substrate support accommodated in the reaction tube along a direction substantially parallel to a surface of the substrate, wherein the gas supply nozzle is provided with a first gas ejection port including an edge vicinity portion and a central portion defined along the direction substantially parallel to the surface of the substrate, and wherein an opening dimension of the edge vicinity portion of the first gas ejection port measured along a direction orthogonal to the direction substantially parallel to the surface of the substrate is greater than an opening dimension of the central portion of the first gas ejection port measured along the direction orthogonal to the direction substantially parallel to the surface of the substrate.

### BRIEF DESCRIPTION OF THE DRAWINGS

FIG. 1 is a diagram schematically illustrating a vertical cross-section of an exemplary configuration of a substrate processing apparatus according to one or more embodiments of the present disclosure.

FIGS. 2A through 2C are diagrams schematically illustrating an exemplary configuration of a gas supply nozzle of the substrate processing apparatus according to the embodiments of the present disclosure, more specifically, FIG. 2A is a diagram schematically illustrating a cross-section of the exemplary configuration of the gas supply nozzle taken along a line A-A in FIG. 1, FIG. 2B is a diagram schematically illustrating an exemplary cross-section of the exemplary configuration of the gas supply nozzle when viewed from a direction of an arrow B in FIG. 2A, and FIG. 2C is a diagram schematically illustrating another exemplary cross-section of the exemplary configuration of the gas supply nozzle when viewed from the direction of the arrow B in FIG. 2A

FIGS. 3A through 3C are diagrams schematically illustrating another exemplary configuration of the gas supply nozzle of the substrate processing apparatus according to the embodiments of the present disclosure, more specifically, FIG. 3A is a diagram schematically illustrating a cross-section of the another exemplary configuration of the gas supply nozzle taken along the line A-A in FIG. 1, FIG. 3B is a diagram schematically illustrating an exemplary cross-section of the another exemplary configuration of the gas supply nozzle when viewed from a direction of an arrow C in FIG. 3A, and FIG. 3C is a diagram schematically illustrating another exemplary cross-section of the another exemplary configuration of the gas supply nozzle when viewed from the direction of the arrow C in FIG. 3A.

FIG. 4 is a block diagram schematically illustrating a configuration of a controller of the substrate processing apparatus according to the embodiments of the present disclosure.

FIG. 5 is a flow chart schematically illustrating a process flow of a substrate processing according to the embodiments of the present disclosure.

FIGS. 6A and 6B are diagrams schematically illustrating a gas flow according to the embodiments of the present disclosure and a gas flow according to a comparative example, more specifically, FIG. 6A is a diagram schematically illustrating the gas flow through the gas supply nozzle of the substrate processing apparatus according to the embodiments of the present disclosure and FIG. 6B is a diagram schematically illustrating the gas flow through a gas supply nozzle of a substrate processing apparatus according to the comparative example.

### DETAILED DESCRIPTION

### Embodiments of Present Disclosure

Hereinafter, one or more embodiments (also simply referred to as “embodiments”) of the technique of the present disclosure will be described in detail with reference to the drawings.

A substrate processing apparatus exemplified in the following description can be used in a manufacturing process of a semiconductor device, and is configured to perform a predetermined treatment process on a substrate to be processed. For example, a silicon wafer (hereinafter, also simply referred to as a “wafer”) may be used as the substrate to be processed. The silicon wafer may serve as a semiconductor substrate on which the semiconductor device is manufactured. Further, in the present specification, the term “wafer” may refer to “a wafer itself”, or may refer to “a wafer and a stacked structure (aggregated structure) of a predetermined layer (or layers) or a film (or films) formed on a surface of the wafer”. That is, the term “wafer” may collectively refer to the wafer and the layers or the films formed on the surface of the wafer. In the present specification, the term “a surface of a wafer” may refer to “a surface (exposed surface) of a wafer itself”, or may refer to “a surface of a predetermined layer or a film formed on a wafer, i.e. a top surface (uppermost surface) of the wafer as a stacked structure”. In the present specification, the terms “substrate” and “wafer” may be used as substantially the same meaning. That is, the term “substrate” may be substituted by “wafer” and vice versa. For example, the predetermined treatment process (hereinafter, may also be simply referred to as “process”) performed on the wafer may include a film-forming process, an annealing process (or a modification process), an oxidation process, a diffusion process, an etching process, a pre-cleaning process and a chamber cleaning process. The present embodiments will be described by way of an example in which the film-forming process is performed as the predetermined treatment process.

(1) Configuration of Substrate Processing Apparatus

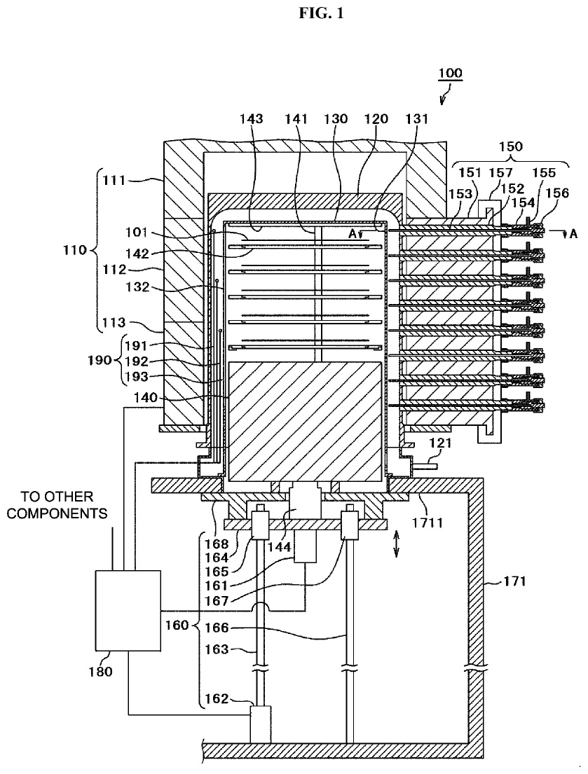

First, a configuration of the substrate processing apparatus according to the present embodiments will be described mainly with reference to FIGS. 1 through 4. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

<Process Chamber>

As shown in FIG. 1, a substrate processing apparatus 100 according to the present embodiments includes a reaction tube 120.

A heater 110 serving as a heating structure (which is a heating apparatus) is provided on an outer side of the reaction tube 120. The heater 110 is capable of heating an inner portion of the reaction tube 120, particularly, an inner portion of an inner tube 130 described later. For example, the heater 110 may be divided into a plurality of zone heaters corresponding to a plurality of blocks divided in a vertical direction (for example, three zone heaters, that is, a first zone heater 111, a second zone heater 112 and a third zone heater 113 shown in FIG. 1). In such a case, the first zone heater 111, the second zone heater 112 and the third zone heater 113 are configured such that a heating state of each of the zone heaters 111, 112 and 113 is capable of being individually controlled based on data of temperature sensors 191, 192 and 193 described later.

The inner tube 130 is provided in an inner side of the reaction tube 120. For example, the inner tube 130 is made of a heat resistant material such as quartz (SiO₂) and silicon carbide (SiC). The inner tube 130 is of a cylindrical shape with a closed upper end and an open lower end. A process chamber in which a wafer 101 is processed is provided in a hollow cylindrical portion of the inner tube 130.

The inner tube 130 is configured such that a substrate support (also referred to as a “boat” or a “substrate retainer”) 140 is capable of being accommodated in the inner tube 130. The substrate support 140 is configured such that a plurality of wafers including the wafer 101 (for example, 25 wafers to 200 wafers) are capable of being supported by (or accommodated in) the substrate support 140 vertically in a horizontal orientation in a multistage manner with their centers aligned one another. Hereinafter, the plurality of wafers including the wafer 101 may also be simply referred to as wafers 101. That is, the substrate support 140 is configured to support the wafers 101 with a predetermined interval therebetween in the multistage manner. For example, the substrate support 140 is made of a heat resistant material such as quartz and silicon carbide (SiC). A plurality of partition plates 142 supported by a partition plate support structure 141 are provided in the substrate support 140 such that the wafers 101 are spaced apart from one another by the plurality of partition plates 142. Further, a top plate 143 is provided at a top of the plurality of partition plates 142.

The substrate support 140 is connected to a boat elevator 160 provided outside the reaction tube 120 through a support column 144. The boat elevator 160 is configured such that the substrate support 140 is capable of being transferred (loaded) into or transferred (unloaded) out of the inner tube 130. That is, boat elevator 160 is capable of taking out the substrate support 140 from an inside of the inner tube 130 to an outside of the inner tube 130 (that is, to a portion below the inner tube 130), or conversely, the boat elevator 160 is capable of inserting the substrate support 140 from the outside of the inner tube 130 (that is, transferring the substrate support 140 from the portion below the inner tube 130) to the inside of the inner tube 130. Further, the boat elevator 160 may be further configured to rotate the substrate support 140 inserted into the inner tube 130.

For example, the boat elevator 160 includes: a table 164 configured to support the support column 144; an upper table 168 placed on the table 164; a rotational driving motor 161 fixed to the table 164 and capable of rotationally driving the support column 144; a vertical driving motor 162 capable of driving the table 164 in the vertical direction; a ball screw 163 connected to the vertical driving motor 162; a ball nut 165 fixed to the table 164 and screwed with the ball screw 163; a guide shaft 166 configured to guide a vertical movement of the table 164; and a ball bearing 167 fixed to the table 164 and configured to receive the vertical movement of the table 164 by the guide shaft 166. The boat elevator 160 is capable of driving the vertical driving motor 162 so as to elevate the upper table 168 until the upper table 168 abuts on an upper surface 1711 of a gantry frame 171 such that the wafers 101 supported by the substrate support 140 are arranged inside the inner tube 130. In such a state, the upper table 168 comes into contact with the upper surface 1711 of the gantry frame 171 to maintain an airtight isolation of an inside of the reaction tube 120 from an outside of the reaction tube 120. Thus, by vacuum-exhausting the inside of the reaction tube 120 through an exhaust pipe 121 by a vacuum exhaust structure (not shown) such as a vacuum pump, it is possible to maintain the inside of the reaction tube 120 in a vacuum state.

A plurality of gas suppliers including a gas supplier (which is a gas supply structure) 150 through which a gas such as a source gas and a reactive gas described later is supplied into the inner tube 130 (that is, into the process chamber) are provided at a side surface of the reaction tube 120. Hereinafter, the plurality of gas suppliers including the gas supplier 150 may also be simply referred to as gas suppliers 150. The gas suppliers 150 are provided in the same plane as the cross-section shown in FIG. 1 such that the gas is supplied to each of the wafers 101 according to a vertical pitch (interval) of the wafers 101 supported by the substrate support 140. Further, the gas suppliers 150 are attached in a direction substantially parallel to surfaces of the wafers 101 supported by the substrate support 140 in the inner tube 130 such that the gas is supplied along the direction substantially parallel to surfaces of the wafers 101. A configuration of the gas supplier 150 will be described in detail later.

Corresponding to the gas suppliers 150, the inner tube 130 is provided with a plurality of gas introduction holes including a gas introduction hole 131 such that the gas supplied through the gas suppliers 150 is capable of being introduced into the inner tube 130 at locations facing front ends (tips) of the gas suppliers 150. Hereinafter, the plurality of gas introduction holes including the gas introduction hole 131 may also be simply referred to as gas introduction holes 131.

In addition, a slit 132 is provided in a portion of a wall surface of the inner tube 130 facing the locations where the gas introduction holes 131 are provided. A part of the gas supplied into the inner tube 130 through the gas introduction holes 131, which did not contribute to a reaction inside the inner tube 130 such as the reaction on the surfaces of the wafers 101 supported by the substrate support 140, is discharged (or exhausted) from the inside of the inner tube 130 toward the reaction tube 120 through the slit 132. Further, the gas discharged from the inside of the inner tube 130 toward the reaction tube 120 through the slit 132 is discharged to the outside of the reaction tube 120 by an exhaust structure (that is, the vacuum exhaust structure described above) (not shown) through the exhaust pipe 121.

A temperature measuring structure (which is a temperature meter) 190 capable of measuring a temperature of a side portion of an inner wall of the reaction tube 120 is provided in the reaction tube 120. For example, as the temperature measuring structure 190, the temperature sensors 191, 192 and 193 are provided at positions corresponding to the first zone heater 111, the second zone heater 112 and the third zone heater 113, respectively. Thereby, the temperature measuring structure 190 is capable of measuring an inner temperature of the reaction tube 120 being heated by the heater 110.

<Gas Supplier>

The gas supplier 150 is configured such that the gas is supplied into the inner tube 130. For example, the gas supplier 150 includes a configuration in which an introduction pipe 152 is inserted inside a main body structure 151. The introduction pipe 152 functions as a gas supply nozzle through which the gas is supplied to the surface of the wafer 101 supported by the substrate support 140 in the inner tube 130 along the direction substantially parallel to the surface of the wafer 101. A gas flow path 153 through which the gas is supplied is provided inside the introduction pipe 152.

A gas ejection port through which the gas flowing through the gas flow path 153 is ejected is provided at an end portion of the introduction pipe 152 facing the inner tube 130. The gas ejection port is arranged such that the gas ejection port is located immediately before the gas introduction hole 131 provided in the inner tube 130. The gas ejection port will be described in detail later. On the other hand, a gas introduction structure 154 and a nut 156 are provided at the other end portion of the introduction pipe 152 opposite to the gas ejection port of the introduction pipe 152. The gas introduction structure 154 is provided with a gas introduction pipe 155 communicating with the introduction pipe 152 such that the gas is supplied to the introduction pipe 152. Further, at the main body structure 151 into which the introduction pipe 152 is inserted, a protrusion cover 157 made of a metal is provided so as to face the gas introduction structure 154.

The gas introduction pipe 155 communicating with the introduction pipe 152 is connected to a gas supply source (not shown), and the gas supplied from the gas supply source is supplied through the gas introduction pipe 155. Further, different types of gases can be supplied from gas supply sources by being switched by a gas type switching structure (not shown). As the different types of gases, for example, the source gas, the reactive gas and an inert gas may be used.

With such a configuration, according to the gas supplier 150, by switching the types of gases supplied from the gas supply sources, it is possible to selectively supply the source gas, the reactive gas or the inert gas into the inner tube 130 through the gas introduction pipe 155 and the introduction pipe 152.

<Gas Supply Nozzle>

Subsequently, with respect to the gas supplier 150, the introduction pipe 152 serving as the gas supply nozzle and a gas ejection port 158 provided at the introduction pipe 152 will be described in more detail.

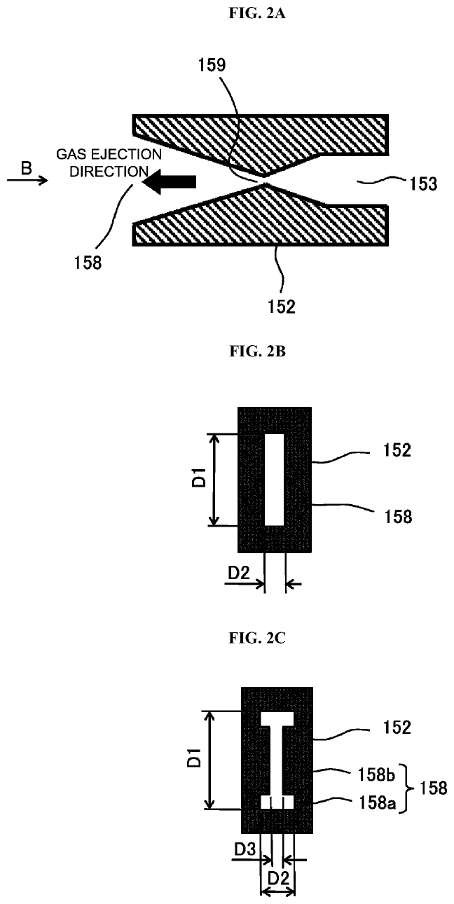

As shown in FIG. 2A, the gas ejection port 158 communicating with the gas flow path 153 is provided at the end portion of the introduction pipe 152 facing the inner tube 130. Further, the source gas, the reactive gas or the inert gas (which is the gas flowing through the gas flow path 153) is ejected toward the wafers 101 supported by the substrate support 140 in the inner tube 130 through the gas ejection port 158.

For example as shown in FIG. 2B, the gas ejection port 158 is, when viewed from a location of gas ejection (that is, when viewed from the inner tube 130), a rectangular shape whose long sides extend along the direction substantially parallel to the surface of the wafer 101 supported by the substrate support 140 in the horizontal orientation (that is, along a horizontal direction). More specifically, the gas ejection port 158, which is of the rectangular shape when viewed from front, is provided such that an opening dimension D1 measured along the direction substantially parallel to the surface of the wafer 101 (that is, the horizontal direction) is 4 to 10 times an opening dimension D2 in a direction (that is, a vertical direction) orthogonal to the direction substantially parallel to the surface of the wafer 101. Further, the opening dimension D1 is provided with a dimension smaller than a diameter of the wafer 101. Further, it is assumed that the opening dimensions D1 and D2 described above are their respective maximum dimensions.

However, the gas ejection port 158 is not limited to the rectangular shape described above. For example, as shown in FIG. 2C, the gas ejection port 158 may be provided with an edge vicinity portion 158a and a central portion 158b defined along the direction substantially parallel to the surface of the wafer 101 (that is, the horizontal direction), and the central portion 158b may be narrower than the edge vicinity portion 158a. That is, the gas ejection port 158 may be configured such that an opening dimension D2 of the edge vicinity portion 158a defined along the direction (that is, the vertical direction) orthogonal to the direction substantially parallel to the surface of the wafer 101 is greater than an opening dimension D3 of the central portion 158b defined along the direction (that is, the vertical direction) orthogonal to the direction substantially parallel to the surface of the wafer 101. Even in such a case, it is assumed that the opening dimension D1 of the gas ejection port 158 measured along the direction substantially parallel to the surface of the wafer 101 (that is, the horizontal direction) is 4 to 10 times the opening dimension D2 of the edge vicinity portion 158a measured along the direction (that is, the vertical direction) orthogonal to the direction substantially parallel to the surface of the wafer 101.

Further, in the introduction pipe 152, for example, as shown in FIG. 2A, a narrow restrictor 159 configured to narrow the gas flow path 153 to reduce a cross-sectional area thereof may be provided in the middle of the gas flow path 153 in the vicinity of the gas ejection port 158. The introduction pipe 152 provided with the narrow restrictor 159 in the gas flow path 153 may constitute a so-called “Laval nozzle”. That is, the introduction pipe 152 may be embodied by a Laval nozzle including the narrow restrictor 159 in the gas flow path 153.

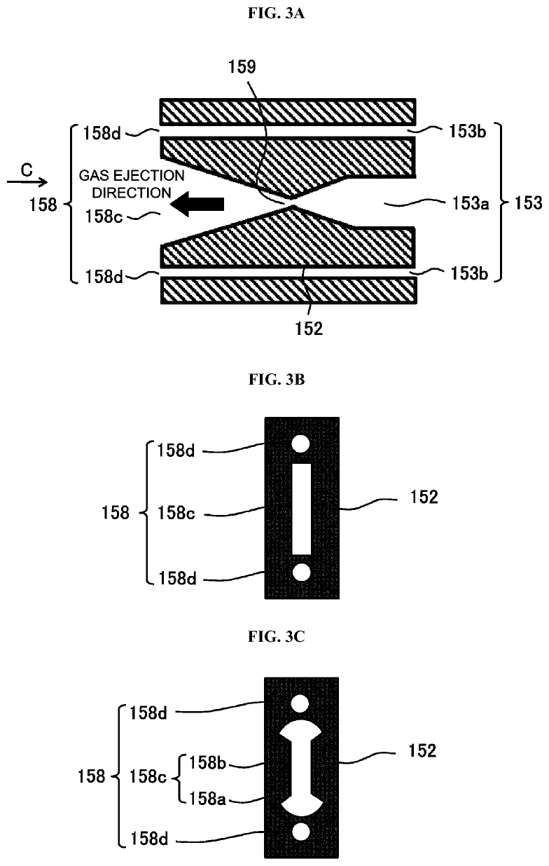

Although the introduction pipe 152 and the gas ejection port 158 are described in detail based on the above specific examples, the introduction pipe 152 and the gas ejection port 158 are not limited to such specific examples. For example, the introduction pipe 152 and the gas ejection port 158 may be embodied by configurations described below. Specifically, for example, as shown in FIG. 3A, the gas flow path 153 of the introduction pipe 152 serving as the gas supply nozzle may include a gas flow path 153a through which a process gas such as the source gas and the reactive gas is supplied and a gas flow path 153b (or gas flow paths) through which the inert gas is supplied. Among the gas flow path 153a and the gas flow path 153b, the gas flow path 153a through which the process gas is supplied may be a Laval nozzle provided with the narrow restrictor 159.

When the gas flow path 153 includes the gas flow path 153a and the gas flow path 153b, as shown in FIGS. 3A and 3B, as the gas ejection port 158, the introduction pipe 152 is provided with a gas ejection port 158c through which the process gas is ejected and a gas ejection port (or gas ejection ports) 158d through which the inert gas is ejected. Among the gas ejection port 158c and the gas ejection port 158d, it is assumed that an opening dimension D1 of the gas ejection port 158c (through which the process gas is ejected) measured along the direction substantially parallel to the surface of the wafer 101 (that is, the horizontal direction) is 4 to 10 times an opening dimension D2 of the gas ejection port 158c measured along the direction (that is, the vertical direction) orthogonal to the direction substantially parallel to the surface of the wafer 101.

Further, for example, as shown in FIG. 3C, the gas ejection port 158c (through which the process gas is ejected) may be provided with the edge vicinity portion 158a and the central portion 158b, and an opening dimension of the edge vicinity portion 158a measured along the direction (that is, the vertical direction) orthogonal to the direction substantially parallel to the surface of the wafer 101 is greater than an opening dimension of the central portion 158b measured along the direction (that is, the vertical direction) orthogonal to the direction substantially parallel to the surface of the wafer 101. Even in such a case, the gas ejection port 158c is not limited to being constituted by linear pieces. For example, the gas ejection port 158c may be of a shape including an arc-shaped side portion as shown in FIG. 3C. The same also applies to the exemplary configuration of the gas ejection port 158 shown in FIG. 2C.

<Controller>

As shown in FIG. 1, the substrate processing apparatus 100 according to the present embodiments includes a controller 180 serving as a control structure (control device) capable of controlling components constituting the substrate processing apparatus 100.

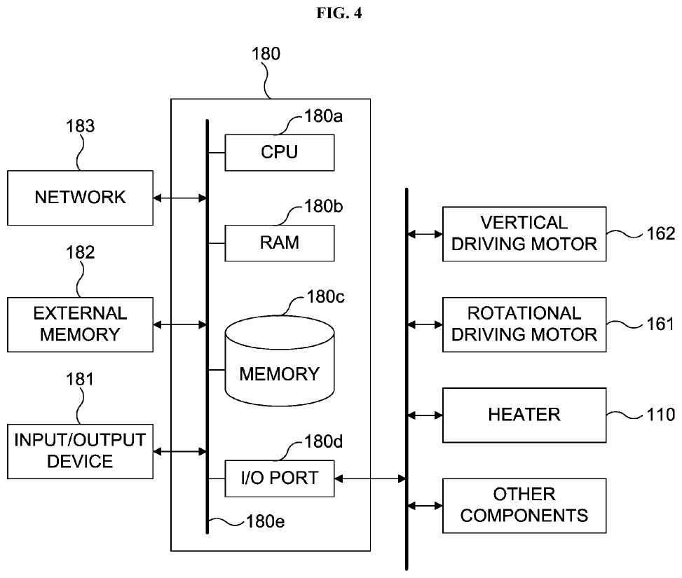

As shown in FIG. 4, the controller 180 is constituted by a computer including a CPU (Central Processing Unit) 180a, a RAM (Random Access Memory) 180b, a memory 180c and an input/output port (also simply referred to as an “I/O port”) 180d. The RAM 180b, the memory 180c and the I/O port 180d may exchange data with the CPU 180a through an internal bus 180e. For example, an input/output device 181 configured by a component such as a touch panel and an external memory 182 may be connected to the controller 180.

The RAM 180b functions as a memory area (work area) where a program or data read by the CPU 180a is temporarily stored.

The memory 180c is configured by a memory medium such as a flash memory and a hard disk drive (HDD). For example, a control program configured to control operations of the substrate processing apparatus 100, a process recipe containing information on sequences and conditions of a substrate processing described later, or a database may be readably stored in the memory 180c. Further, the process recipe is obtained by combining sequences (steps) of the substrate processing described later such that the controller 180 can execute the steps to acquire a predetermined result, and functions as a program. Hereafter, the process recipe and the control program may be collectively or individually referred to as a “program”. Thus, in the present specification, the term “program” may refer to the process recipe alone, may refer to the control program alone, or may refer to both of the process recipe and the control program.

The I/O port 180d is electrically connected to components of the substrate processing apparatus 100 such as the heater 110, the rotational driving motor 161 and the vertical driving motor 162 of the boat elevator 160, a substrate loading/unloading port (not shown), a mass flow controller (not shown) and the vacuum pump (not shown).

In addition, in the present specification, “electrically connected” means that the components are connected by physical cables or the components are capable of communicating with one another to transmit and receive signals (electronic data) to and from one another directly or indirectly. For example, a device for relaying the signals or a device for converting or computing the signals may be provided between the components.

The CPU 180a is configured to read and execute the control program from the memory 180c and read the process recipe from the memory 180c in accordance with an instruction such as an operation command inputted from the controller 180. The CPU 180a is configured to be capable of controlling various operations in accordance with the contents of the read process recipe such as an operation of supplying electrical power to the heater 110, a driving operation of the rotational driving motor 161 of the boat elevator 160, a driving operation of the vertical driving motor 162 of the boat elevator 160 and an opening and closing operation of the substrate loading/unloading port (not shown).

The controller 180 is not limited to a dedicated computer, and the controller 180 may be embodied by a general-purpose computer. For example, the controller 180 according to the present embodiments may be embodied by preparing the external memory 182 (e.g., a magnetic tape, a magnetic disk such as a flexible disk and a hard disk, an optical disk such as a CD and a DVD, a magneto-optical disk such as an MO, a semiconductor memory such as a USB memory and a memory card) in which the above-described program is stored, and installing the program onto the general-purpose computer using the external memory 182.

A method of providing the program to the computer is not limited to the method using the external memory 182. For example, the program may be directly provided to the computer by a communication instrument such as a network 183 (Internet and a dedicated line) instead of the external memory 182. In addition, the memory 180c and the external memory 182 may be embodied by a non-transitory computer-readable recording medium. Hereinafter, the memory 180c and the external memory 182 may be collectively or individually referred to as a recording medium. Thus, in the present specification, the term “recording medium” may refer to the memory 180c alone, may refer to the external memory 182 alone, or may refer to both of the memory 180c and the external memory 182.

<Substrate Processing>

Hereinafter, the substrate processing (which is a part of the manufacturing process of the semiconductor device) of performing a process with respect to the wafer 101 using the substrate processing apparatus 100 described above will be described.

The substrate processing according to the present embodiments will be described by way of an example in which a film-forming process of forming a silicon oxide (SiO2) film serving as a silicon-containing film on the wafer 101. The film-forming process is performed in the reaction tube 120 of the substrate processing apparatus 100 described above. In the following descriptions, operations of the components constituting the substrate processing apparatus 100 are controlled by executing the program stored in the memory 180c of the controller 180.

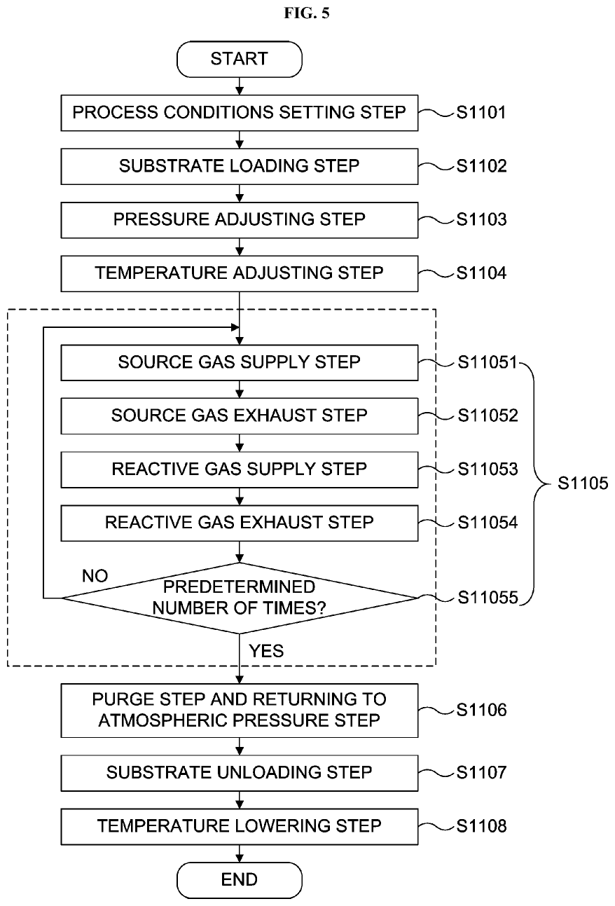

FIG. 5 is a flow chart schematically illustrating a process flow of the substrate processing according to the present embodiments.

<Process Conditions Setting Step: S1101>

As shown in FIG. 5, in the film-forming process serving as the substrate processing, first, the CPU 180a of the controller 180 reads the process recipe and the related database stored in the memory 180c and sets process conditions. As main items of the process recipe, an item such as a flow rate of the gas, temperature data and the number of executions of a process cycle may be used.

<Substrate Loading Step: S1102>

After the process conditions are set, with the wafers 101 placed on and supported by the substrate support 140 one by one, the substrate support 140 is elevated by operating the vertical driving motor 162 of the boat elevator 160 such that the substrate support 140 is transferred (loaded) into the inner tube 130 installed inside the reaction tube 120.

<Pressure Adjusting Step: S1103>

After the substrate loading step S1102 is performed, with the substrate support 140 loaded in the inner tube 130, an inner atmosphere of the reaction tube 120 is vacuum-exhausted by the vacuum pump (not shown) through the exhaust pipe 121. Then, based on the process recipe read in the step S1101, an inner pressure of the reaction tube 120 is adjusted such that the inner pressure of the reaction tube 120 reaches and is maintained at a desired pressure (vacuum level).

<Temperature Adjusting Step: S1104>

In a state where the inner atmosphere of the reaction tube 120 is vacuum-exhausted, the heater 110 heats the inside of the reaction tube 120. When heating the inside of reaction tube 120, an amount of the electric current (or the voltage) supplied (or applied) to each of the zone heaters 111, 112 and 113 of the heater 110 is feedback-controlled by using temperature information measured by the temperature sensors 191, 192 and 193 such that a desired temperature distribution of the inner temperature of the reaction tube 120 can be obtained. A temperature control of feedback-controlling the amount of the electric current (or the voltage) is continuously performed until at least a processing of the wafer 101 is completed.

Further, in the temperature adjusting step S1104, the substrate support 140 is rotated at a constant speed by operating the rotational driving motor 161 of the boat elevator 160. In the temperature adjusting step S1104, by using the temperature information measured by the temperature sensors 191, 192 and 193, a rotational speed of the substrate support 140 may be increased above a pre-set rotational speed by controlling the operation of the rotational driving motor 161 when a predicted temperature at each of a plurality of locations in the vicinity of the surface of the wafer 101 is higher than a pre-set temperature, and the rotational speed of the substrate support 140 may be decreased below the pre-set rotational speed by controlling the operation of the rotational driving motor 161 when the predicted temperature is lower than the pre-set temperature.

<Predetermined Film Forming Step: S1105>

Subsequently, a step of forming a first film (that is, a predetermined film forming step S1105) is performed. For example, a source gas supply step S11051, a source gas exhaust step S11052, a reactive gas supply step S11053, a reactive gas exhaust step S11054 and a determination step S11055 are performed as the predetermined film forming step S1105.

<Source Gas Supply Step: S11051>

First, the rotational speed of the substrate support 140 supporting the wafer 101 is maintained at the pre-set rotational speed with respect to the wafer 101 accommodated in the inner tube 130. In such a state, a first gas serving as the source gas whose flow rate is adjusted is supplied through the introduction pipe 152 of the gas supplier 150. Then, the source gas is ejected through the gas ejection port 158 of the introduction pipe 152, and is supplied into the inner tube 130 through the gas introduction hole 131. Thereby, the first gas such as Si₂Cl₆ gas is supplied with respect to the wafer 101 supported by the substrate support 140. For example, the flow rate of the first gas supplied to the wafer 101 may be set within a range from 0.002 slm (standard liter per minute) to 1 slm, and more preferably, within a range from 0.1 slm to 1 slm. When supplying the first gas, the inert gas serving as a carrier gas may be supplied. For example, a flow rate of the carrier gas may be set within a range from 0.01 slm to 5 slm, and more preferably, within a range from 0.5 slm to 5 slm.

By supplying the first gas into the inner tube 130, a first layer (whose thickness is, for example, within a range from less than a single atomic layer to several atomic layers) is formed on the wafer 101 (that is, on a base film on the surface of the wafer 101).

Further, a part of the source gas and the carrier gas supplied through the introduction pipe 152 (which did not contribute to the reaction on the surface of the wafer 101) flows out to the reaction tube 120 through the slit 132 provided in the inner tube 130, and is exhausted through the exhaust pipe 121.

<Source Gas Exhaust Step: S11052>

After the first layer is formed on the surface of the wafer 101 by supplying the first gas serving as the source gas for a predetermined time, a supply of the first gas is stopped. Then, the inner atmosphere of the reaction tube 120 is vacuum-exhausted by the vacuum pump (not shown) to remove a residual gas in the reaction tube 120 and the inner tube 130 such as the first gas which did not react or which contributed to the formation of the first layer out of the reaction tube 120 and the inner tube 130.

In the source gas exhaust step S11052, the inert gas is continuously supplied through the introduction pipe 152. The inert gas serves as a purge gas, which improves the efficiency of removing the residual gas in the reaction tube 120 such as the first gas which did not react or which contributed to the formation of the first layer out of the reaction tube 120 and the inner tube 130.

<Reactive Gas Supply Step: S11053>

After the residual gas in the reaction tube 120 and the inner tube 130 is removed, with respect to the wafer 101 accommodated in the inner tube 130, a second gas serving as the reactive gas whose flow rate is adjusted is supplied through the introduction pipe 152 of the gas supplier 150. When supplying the second gas through the introduction pipe 152, the second gas is ejected through the gas ejection port 158 of the introduction pipe 152, and is supplied into the inner tube 130 through the gas introduction hole 131. Thereby, the second gas such as O₂ gas is supplied with respect to the wafer 101 supported by the substrate support 140. For example, the flow rate of the second gas supplied to the wafer 101 may be set within a range from 0.2 slm to 10 slm, and more preferably, within a range from 1 slm to 5 slm.

When supplying the second gas, a supply of the carrier gas through the introduction pipe 152 is stopped in order to prevent the carrier gas from being supplied into the reaction tube 120 together with the second gas. That is, the second gas is supplied into the reaction tube 120 and the inner tube 130 without being diluted with the carrier gas. As a result, it is possible to improve a film-forming rate of a layer (that is, a second layer described below). In the reactive gas supply step S11053, a temperature of the heater 110 is set to substantially the same temperature as that of the heater 110 in the source gas supply step S11051.

In the reactive gas supply step S11053, the second gas is supplied into the reaction tube 120 and the inner tube 130 without any other gas being supplied into the reaction tube 120 and the inner tube 130 together with the second gas. A substitution reaction occurs between the second gas and at least a portion of the first layer formed on the wafer 101 in the source gas supply step S11051. During the substitution reaction, for example, silicon (Si) contained in the first layer and oxygen (O) contained in the second gas are bonded together. As a result, a silicon oxide (SiO2) layer serving as the second layer containing silicon and oxygen is formed on the wafer 101.

<Reactive Gas Exhaust Step: S11054>

After the second layer is formed on the surface of the wafer 101 by supplying the second gas serving as the reactive gas for a predetermined time, a supply of the second gas is stopped. Then, the residual gas in the reaction tube 120 and the inner tube 130 such as the O₂ gas which did not react or which contributed to the formation of the SiO₂ layer and reaction by-products are removed out of the reaction tube 120 and the inner tube 130 in the same manners as in the source gas exhaust step S11052.

<Determination Step (Performing a Predetermined Number of Times): S11055>

By performing a cycle of the predetermined film forming step S1105 in which the source gas supply step S11051 through the reactive gas exhaust step S11054 described above are sequentially performed in this order a predetermined number of times (that is, one or more times), the SiO₂ film of a predetermined thickness (for example, 0.1 nm to 2 nm) is formed on the wafer 101. It is preferable that the cycle described above is repeatedly performed a plurality of times, for example, preferably about 10 times to 80 times, and more preferably about 10 times to 15 times. Thereby, it is possible to form the film such as the SiO₂ film with a uniform thickness distribution on the surface of the wafer 101.

That is, by repeatedly performing a series of steps (that is, the step S11051 through the step S11055) described above a predetermined number of times, the film of a predetermined thickness is formed on the wafer 101. Thereby, the predetermined film forming step S1105 is completed.

<Purge Step and Returning to Atmospheric Pressure Step: S1106>

After the predetermined film forming step S1105 is completed, the inert gas serving as the carrier gas is supplied into the reaction tube 120 and the inner tube 130 through the introduction pipe 152 such that the gas is exhausted through the exhaust pipe 121. The inert gas serves as the purge gas, and inner atmospheres of the reaction tube 120 and the inner tube 130 are purged with the inert gas. Thereby, the residual gas in the reaction tube 120 and the inner tube 130 and the by-products remaining in the reaction tube 120 and the inner tube 130 are removed out of the reaction tube 120. Then, the inert gas is filled in the reaction tube 120 until the inner pressure of the reaction tube 120 reaches an atmospheric pressure. Further, by stopping an application of the electrical power to each of the zone heaters 111, 112 and 113 of the heater 110, a heating by the heater 110 is stopped. The operation of the rotational driving motor 161 of the boat elevator 160 is stopped, and a rotation of the substrate support 140 is stopped.

<Substrate Unloading Step: S1107>

Thereafter, by operating the vertical driving motor 162 of the boat elevator 160, the substrate support 140 is lowered from the inner tube 130 of the reaction tube 120. Then, the wafer 101 with the film of the predetermined thickness formed on the surface thereof is transferred (discharged) out of the substrate support 140.

<Temperature Lowering Step: S1108>

Then, the processing of the wafer 101 (that is, the substrate processing described above) is completed by lowering the temperature of the heater 110 with the application of the electrical power to each of the zone heaters 111, 112 and 113 of the heater 110 stopped.

(3) Gas Flow with Respect to Wafer

Subsequently, a gas flow in the predetermined film forming step S1105 of the substrate processing described above when the gas (in particular, the process gas such as the source gas and the reactive gas) is supplied with respect to the wafer 101.

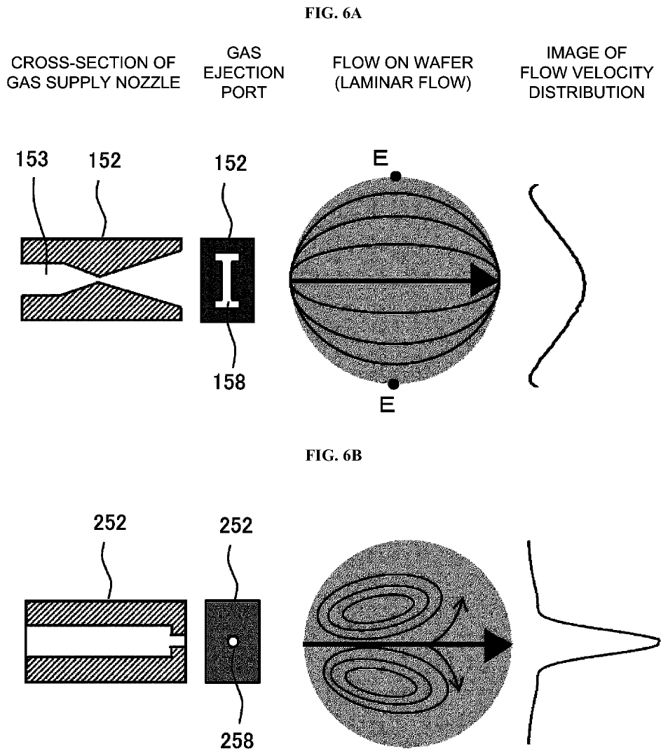

FIGS. 6A and 6B are diagrams schematically illustrating the gas flow through the gas supply nozzle of the substrate processing apparatus 100 according to the present embodiments and a gas flow through a gas supply nozzle of a substrate processing apparatus according to a comparative example, respectively.

Before describing the gas flow according to the present embodiments, a gas flow by a general nozzle configuration (that is, the gas flow according to the comparative example) will be briefly described.

In the general nozzle configuration, for example as shown in FIG. 6B, a gas ejection port 258 of an introduction pipe 252 may be a round hole shape when viewed from front. When the process gas is ejected through the gas ejection port 258 of the round hole shape, a flow velocity distribution may follow a convex distribution in which a flow velocity at a center of the nozzle is higher than those at the other locations. Therefore, a vortex of the gas flow may be generated on the surface of the wafer of the location of gas ejection, and the process gas may be stagnant there. When the process gas is stagnant, the stagnant gas is exposed to the heat. Thereby, for example, when the stagnant gas is the source gas, the source gas will become in a highly decomposed state. As a result, a difference (non-uniformity) in a degree of decomposition may occur on the wafer. Further, in a location far from the center of the nozzle, the gas flow becomes weak (that is, the flow velocity of the gas is low), and the degree of decomposition may also be high at the location far from the center of the nozzle. That is, when the gas ejection port 258 of the introduction pipe 252 is of the round hole shape, it may be difficult to uniformly supply the process gas on the surface of the wafer.

On the other hand, according to the present embodiments, for example, as shown in FIG. 6A, the gas ejection port 158 of the introduction pipe 152 is of the rectangular shape in which the opening dimension D1 measured along the direction substantially parallel to the surface of the wafer 101 (that is, the horizontal direction) is 4 to 10 times the opening dimension D2 measured along the direction (that is, a vertical direction) orthogonal to the direction substantially parallel to the surface of the wafer 101. That is, the gas ejection port 158 is of a widened shape in which a length along a width direction (that is, the horizontal direction) is about 4 to 10 times a length along a longitudinal direction (that is, the vertical direction). When the process gas is ejected through the gas ejection port 158 of the widened shape, it is possible to supply the gas over a wide range in the lateral direction (that is, the horizontal direction). Therefore, as compared with a case in which the gas ejection port 258 of the round hole shape is used, it is possible to obtain a flow velocity distribution in which an increase in the flow velocity at the center of the nozzle is suppressed (that is, a flow velocity distribution in which a degree of convexity is suppressed). Therefore, it is possible to form a laminar flow without the vortex of the gas flow on the surface of the wafer 101 to which the gas is ejected, and it is possible to prevent the process gas from being stagnant. That is, it is possible to uniformly supply the gas on the surface of the wafer 101, and as a result, it is also possible to suppress the difference (non-uniformity) in the degree of decomposition on the wafer 101.

In order to suppress the degree of the convexity of the flow velocity distribution and to form the laminar flow without the vortex of the gas flow, it is preferable that the opening dimension D1 of the gas ejection port 158 is 4 to 10 times the opening dimension D2 of the gas ejection port 158, more preferably, 6 to 8 times the opening dimension D2 of the gas ejection port 158. When the opening dimension D1 is less than four times the opening dimension D2, the flow velocity at the center of the nozzle and the degree of the convexity of the flow velocity distribution may not be sufficiently suppressed. Further, when the opening dimension D1 exceeds 10 times the opening dimension D2, due to a limitation of an overall size of the introduction pipe 152, a sufficient size of the opening dimension D2 may not be secured, and it may be difficult to supply the gas at a desired and sufficient flow rate to the wafer 101.

Further, when the gas ejection port 158 includes the edge vicinity portion 158a and the central portion 158b and when the opening dimension D2 of the edge vicinity portion 158a is greater than then opening dimension D3 of the central portion 158b, it is possible to suitably adjust a conductance of the gas flow on the surface of the wafer 101. Specifically, since the central portion 158b serves as a resistance (or a throttle) when the gas is ejected, the flow rate of the gas through the edge vicinity portion 158a is increased. Thereby, it is possible to supply the gas at a high flow velocity even to a location far from a center of the wafer (for example, a point “E” in FIG. 6A). Therefore, it is possible to eject the gas evenly (or uniformly) onto the surface of the wafer 101, which is highly preferable for uniformly supplying the gas onto the surface of the wafer 101. Further, the opening dimension D1 may be made smaller than the diameter of the wafer 101.

Further, when the narrow restrictor 159 is provided in the middle of the gas flow path 153 and thereby the introduction pipe 152 is embodied by the Laval nozzle with the narrow restrictor 159, it is possible to form the gas flow path 153 with a tapered shape which gradually widens from the narrow restrictor 159 to the gas ejection port 158, and as a result, it is possible to provide a structure capable of suppressing a separation of the gas flow and an expansion loss of the gas flow. That is, by suppressing the energy loss of the gas flow between the narrow restrictor 159 and the gas ejection port 158, it is possible to obtain a high flow velocity of the gas. Therefore, it is possible to form the laminar flow without the vortex by suppressing the convex distribution of flow velocity, which is highly preferable for uniformly supplying the gas onto the surface of the wafer 101.

The gas flow described above is mainly for the process gas, and the description of the gas flow may not be applied to the inert gas serving as the purge gas, for example. That is, regarding the process gas, process results in the source gas supply step S11051 and the reactive gas supply step S11053 of the predetermined film forming step S1105 are greatly affected by supplying the gas uniformly onto the surface of the wafer 101. However, regarding the inert gas serving as the purge gas, as long as the residual gas or the like can be removed, the degree of the convexity of the flow velocity distribution may not be suppressed. Therefore, as shown in FIGS. 3B and 3C, the gas ejection port 158 of the introduction pipe 152 may include two separate gas ejection ports, i.e., the gas ejection port 158c through which the process gas is ejected and the gas ejection port (or gas ejection ports) 158d through which the inert gas is ejected.

Further, for example, the Si₂Cl₆ (disilicon hexachloride) gas may be used as the first gas (silicon-containing gas), and a gas such as the O₂ (oxygen) gas, O₃ (ozone) gas and H₂O (water) may be used as the second gas (oxygen-containing gas), and a gas such as the N₂ (nitrogen) gas and Ar (argon) gas may be used as the carrier gas (inert gas).

While the present embodiments are described by way of an example in which the SiO₂ film is formed on the wafer 101, the present embodiments are not limited thereto. For example, instead of the SiO₂ film, the present embodiments may also be applied when a silicon nitride film (Si₃N₄ film) or a titanium nitride film (TiN film) is formed. In addition, the present embodiments may also be applied to form another films other than the films described above. For example, the present embodiments may also be applied to form a film containing an element such as tungsten (W), tantalum (Ta), ruthenium (Ru), molybdenum (Mo), zirconium (Zr), hafnium (Hf), aluminum (Al), silicon (Si), germanium (Ge) and gallium (Ga), a film containing an element of the same family as the elements described above, a compound film of one or more elements described above and nitrogen (that is, a nitride film) or a compound film of one or more elements described above and oxygen (that is, an oxide film). Further, when forming the films described above, a halogen-containing gas or a gas containing at least one of a halogen element, an amino group, a cyclopentane group, oxygen (O), carbon (C) or an alkyl group may be used.

(4) Effects according to Present Embodiments

According to the present embodiments, it is possible to provide one or more of the following effects.

(a) According to the present embodiments, the opening dimension D1 of the gas ejection port 158 of the introduction pipe 152 serving as the gas supply nozzle measured along the direction substantially parallel to the surface of the wafer 101 is 4 to 10 times the opening dimension D2 of the gas ejection port 158 measured along the direction orthogonal to the direction substantially parallel to the surface of the wafer 101. Therefore, it is possible to supply the gas over a wide range in the direction substantially parallel to the surface of the wafer 101, and it is also possible to obtain the flow velocity distribution in which the increase in the flow velocity at the center of the nozzle is suppressed (that is, the flow velocity distribution in which the degree of convexity is suppressed). Thus, according to the present embodiments, it is possible to form the laminar flow without the vortex of the gas flow on the surface of the wafer 101. Further, since it is possible to prevent the process gas from being stagnant, it is possible to uniformly supply the gas on the surface of the wafer 101, and as a result, it is also possible to suppress the difference (non-uniformity) in the degree of decomposition on the wafer 101. That is, according to the present embodiments, it is possible to uniformly supply the gas on the surface of the wafer 101 when the wafer 101 is processed, and for example, when the processing of the wafer 101 is the film-forming process, it is possible to improve a uniformity of the film formed on the surface of the wafer 101, and it is also possible to improve a step coverage property of the film formed on the wafer 101.

(b) According to the present embodiments, when the opening dimension D2 of the edge vicinity portion 158a of the gas ejection port 158 is greater than the opening dimension D3 of the central portion 158b of the gas ejection port 158, since the central portion 158b serves as the resistance (or the throttle) when the gas is ejected, it is possible to supply the gas at a high flow velocity even to the location far from the center of the wafer 101. Therefore, according to the present embodiments, by suitably adjusting the conductance of the gas flow on the surface of the wafer 101, it is possible to eject the gas evenly (or uniformly) onto the surface of the wafer 101, which is highly preferable for uniformly supplying the gas onto the surface of the wafer 101.

(c) According to the present embodiments, when the introduction pipe 152 serving as the gas supply nozzle is embodied by the Laval nozzle provided with the narrow restrictor 159 in the gas flow path 153, it is possible to provide the structure capable of suppressing the separation of the gas flow and the expansion loss of the gas flow between the narrow restrictor 159 and the gas ejection port 158. Therefore, according to the present embodiments, by suppressing the energy loss of the gas flow between the narrow restrictor 159 and the gas ejection port 158, it is possible to obtain the high flow velocity of the gas. Therefore, it is possible to form the laminar flow without the vortex by suppressing the convex distribution of the flow velocity, which is highly preferable for uniformly supplying the gas onto the surface of the wafer 101.

(5) Modified Examples and Other Embodiments

While the technique of the present disclosure is described in detail by way of the above-described embodiments, the technique of the present disclosure is not limited thereto. The technique of the present disclosure may be modified in various ways without departing from the scope thereof

For example, while the above-described embodiments are described by way of an example in which, as shown in FIGS. 2C and 3C, the gas ejection port 158 is provided with the edge vicinity portion 158a and the central portion 158b and the central portion 158b is narrower than the edge vicinity portion 158a, the technique of the present disclosure is not limited thereto. For example, as shown in FIGS. 2B and 3B, the gas ejection port 158 may be the rectangular shape when viewed from front or back. Further, the shape of the gas ejection port 158 is not limited to the rectangular shape described above. For example, the gas ejection port 158 may be of an oval shape. Further, while the above-described embodiments are described by way of an example in which the introduction pipe 152 is embodied by the Laval nozzle, the technique of the present disclosure is not limited thereto. That is, the vicinity of the gas ejection port 158 of the introduction pipe 152 may not be provided with a structure such as the narrow restrictor 159 and a tapered portion. Further, even when the tapered portion is provided at the vicinity of the gas ejection port 158, a surface of the tapered portion may not be limited to a planar surface and may be a stepped surface instead.

Further, while the above-described embodiments are described by way of an example in which the SiO₂ film is formed on the wafer 101, the technique of the present disclosure is not limited thereto. For example, instead of the SiO₂ film, the technique of the present disclosure may also be applied when the silicon nitride film (Si₃N₄ film) or the titanium nitride film (TiN film) is formed. In addition, the technique of the present disclosure may also be applied to form another films other than the films described above. For example, the technique of the present disclosure may also be applied to form a film containing an element such as tungsten (W), tantalum (Ta), ruthenium (Ru), molybdenum (Mo), zirconium (Zr), hafnium (Hf), aluminum (Al), silicon (Si), germanium (Ge) and gallium (Ga), a film containing an element of the same family as the elements described above, a compound film of one or more elements described above and nitrogen (that is, a nitride film) or a compound film of one or more elements described above and oxygen (that is, an oxide film). Further, when forming the films described above, the halogen-containing gas or the gas containing at least one of the halogen element, the amino group, the cyclopentane group, oxygen (O), carbon (C) or the alkyl group may be used.

Further, while the above-described embodiments are described by way of an example in which the film-forming process is performed as the substrate processing, the technique of the present disclosure is not limited thereto. That is, in addition to the film-forming process or instead of the film-forming process, the technique of the present disclosure can be applied to a process such as the annealing process, the diffusion process, the oxidation process, a nitridation process and a lithography process, as long as the process is performed by supplying the gas to the wafer (substrate) to be processed. The technique of the present disclosure may also be applied to other substrate processing apparatuses such as an annealing apparatus, an etching apparatus, an oxidation apparatus, a nitridation apparatus, an exposure apparatus, a coating apparatus, a drying apparatus, a heating apparatus, an apparatus using the plasma and combinations thereof. The technique of the present disclosure may also be applied when a constituent of one of the above-described examples is substituted with another constituent of other examples, or when a constituent of one of the above-described examples is added to other examples. The technique of the present disclosure may also be applied when the constituent of the examples is omitted or substituted, or when a constituent is added to the examples.

According to some embodiments of the present disclosure, it is possible to uniformly supplying the gas with respect to the surface of the substrate when the substrate is processed.

What is claimed is:

1. A substrate processing apparatus comprising:
a reaction tube in which a substrate support configured to support a substrate is accommodated; and
a gas supply nozzle through which a gas is supplied with respect to the substrate supported by the substrate support accommodated in the reaction tube along a direction substantially parallel to a surface of the substrate,
wherein the gas supply nozzle is provided with a first gas ejection port comprising an edge vicinity portion and a central portion defined along the direction substantially parallel to the surface of the substrate, and
wherein an opening dimension of the edge vicinity portion of the first gas ejection port measured along a direction orthogonal to the direction substantially parallel to the surface of the substrate is greater than an opening dimension of the central portion of the first gas ejection port measured along the direction orthogonal to the direction substantially parallel to the surface of the substrate.

2. The substrate processing apparatus of claim 1, wherein the first gas ejection port is configured such that an opening dimension of the first gas ejection port measured along the direction parallel to the surface of the substrate is 4 to 10 times an opening dimension of the first gas ejection port measured along the direction orthogonal to the direction substantially parallel to the surface of the substrate

3. The substrate processing apparatus of claim 1, wherein the gas supply nozzle is provided with a narrow restrictor in a gas flow path communicating with the first gas ejection port.

4. The substrate processing apparatus of claim 1, wherein the first gas ejection port is, when viewed from a location of gas ejection, of a rectangular shape whose long sides extend along the direction substantially parallel to the surface of the substrate.

5. The substrate processing apparatus of claim 1, wherein the first gas ejection port is, when viewed from a location of gas ejection, configured such that the central portion is narrower than the edge vicinity portion.

6. The substrate processing apparatus of claim 1, wherein an opening dimension of the first gas ejection port is smaller than a diameter of the substrate.

7. The substrate processing apparatus of claim 3, wherein the gas supplied through the gas flow path comprises a process gas.

8. The substrate processing apparatus of claim 7, wherein the process gas is a source gas or a reactive gas.

9. The substrate processing apparatus of claim 7, wherein the gas supply nozzle is provided with an inert gas flow path through which an inert gas is supplied and different from the gas flow path.

10. The substrate processing apparatus of claim 9, wherein the gas supply nozzle is further provided with one or more second gas ejection ports through which the inert gas is ejected.

11. The substrate processing apparatus of claim 10, wherein the one or more second gas ejection ports are provided such that the first gas ejection port is interposed between the one or more second gas ejection ports.

12. The substrate processing apparatus of claim 1, wherein the substrate support is configured to support a plurality of substrates comprising the substrate, and
wherein a plurality of gas supply nozzles comprising the gas supply nozzle are provided such that the gas is supplied with respect to the plurality of substrates through the plurality of gas supply nozzles, respectively.

13. The substrate processing apparatus of claim 12, wherein the plurality of gas supply nozzles are provided along a direction in which the plurality of substrates are arranged in a multistage manner.

14. The substrate processing apparatus of claim 1, further comprising
a heater provided around the reaction tube and configured to heat the substrate.

15. A method of manufacturing a semiconductor device, comprising:
(a) accommodating a substrate support configured to support a substrate in a reaction tube; and
(b) processing the substrate by supplying a gas with respect to the substrate supported by the substrate support accommodated in the reaction tube along a direction substantially parallel to a surface of the substrate through a side surface of the reaction tube,
wherein the gas is supplied through a gas supply nozzle provided with a first gas ejection port comprising an edge vicinity portion and a central portion defined along the direction substantially parallel to the surface of the substrate, and
wherein an opening dimension of the edge vicinity portion of the first gas ejection port measured along a direction orthogonal to the direction substantially parallel to the surface of the substrate is greater than an opening dimension of the central portion of the first gas ejection port measured along the direction orthogonal to the direction substantially parallel to the surface of the substrate.

16. A non-transitory computer-readable recording medium storing a program that causes, by a computer, a substrate processing apparatus to perform:
(a) accommodating a substrate support configured to support a substrate in a reaction tube; and
(b) processing the substrate by supplying a gas with respect to the substrate supported by the substrate support accommodated in the reaction tube along a direction substantially parallel to a surface of the substrate through a side surface of the reaction tube,
wherein the gas is supplied through a gas supply nozzle provided with a first gas ejection port comprising an edge vicinity portion and a central portion defined along the direction substantially parallel to the surface of the substrate, and
wherein an opening dimension of the edge vicinity portion of the first gas ejection port measured along a direction orthogonal to the direction substantially parallel to the surface of the substrate is greater than an opening dimension of the central portion of the first gas ejection port measured along the direction orthogonal to the direction substantially parallel to the surface of the substrate.
